(19) United States
(12) Patent Application Publication
(10) Pub. No.: US 2026/0038575 A1
(43) Pub. Date: Feb. 5, 2026

(54) MEMORY DEVICE AND MEMORY SYSTEM

(71) Applicant: SK hynix Inc., Gyeonggi-do (KR)

(72) Inventors: Dong Hee HAN, Gyeonggi-do (KR); Seong Yoon KANG, Gyeonggi-do (KR); Mun Seon JANG, Gyeonggi-do (KR); Sang Uhn CHA, Gyeonggi-do (KR)

(21) Appl. No.: 18/951,652

(22) Filed: Nov. 19, 2024

(30) Foreign Application Priority Data
Aug. 2, 2024 (KR) 10-2024-0102966

(51) Int. Cl. G11C 11/408; G11C 11/4091; G11C 11/4093; G11C 29/44

(52) U.S. Cl. CPC G11C 11/4085; G11C 11/4093; G11C 29/44; G11C 11/4091

(57) ABSTRACT

A memory device includes a memory cell array including a plurality of cell blocks, each cell block including a plurality of memory cells and sharing sub-word line drivers with adjacent cell blocks; a data input/output circuit configured to input and output data corresponding to the plurality of cell blocks through a plurality of data pads; and a mapping circuit disposed between the memory cell array and the data input/output circuit, and configured to control a mapping between the plurality of cell blocks and the plurality of data pads, while adjusting, according to an output control signal, a number of bits of data output from cell blocks sharing activated sub-word line drivers.

### CROSS-REFERENCE TO RELATED APPLICATIONS

The present application claims the benefit of Korean Patent Application No. 10-2024-0102966, filed on Aug. 2, 2024, which is incorporated herein by reference in its entirety.

### BACKGROUND

### 1. Field

Various embodiments of the present disclosure relate to a semiconductor design technology, and more particularly, to a memory system including a memory device capable of responding to a fault by a sub-word line driver.

### 2. Description of the Related Art

In the early days of the semiconductor memory industry, there were many original good dies with no defective memory cells, in a memory chip that has passed a semiconductor fabrication process on the wafer. However, as the capacity of memory devices gradually increases, it becomes difficult to make a memory device completely free of a defective memory cell, and at present, it may be said that there is likely no possibility that a memory device with no defective memory cell is fabricated. As one solution to overcome this situation, a method of repairing defective memory cells of a memory device with redundant memory cells or a method of correcting an error in data of memory cells using an error correction circuit is being used. Currently, various methods are being discussed to manage the

maximum number of error bits that may occur in a memory device within an error correction capability of a memory controller.

### SUMMARY

Embodiments of the present disclosure are directed to a memory device and a memory system capable of changing a mapping between data pads and cell blocks sharing a sub-word line driver, to thereby adjust the number of bits of data output by the shared sub-word line driver.

In accordance with an embodiment of the present disclosure, a memory device includes a memory cell array including a plurality of cell blocks, each cell block including a plurality of memory cells and sharing sub-word line drivers with adjacent cell blocks; a data input/output circuit configured to input and output data corresponding to the plurality of cell blocks through a plurality of data pads; and a mapping circuit disposed between the memory cell array and the data input/output circuit, and configured to control a mapping between the plurality of cell blocks and the plurality of data pads, while adjusting, according to an output control signal, a number of bits of data output from cell blocks sharing activated sub-word line drivers.

In accordance with another embodiment of the present disclosure, a memory device includes a memory cell array including a plurality of cell groups, each group including two adjacent cell blocks among a plurality of cell blocks and sharing sub-word line drivers with adjacent cell groups; a data input/output circuit configured to input and output data corresponding to the plurality of cell blocks through a plurality of data pads; and a mapping circuit disposed between the memory cell array and the data input/output circuit, and configured to control a mapping between the plurality of cell blocks and the plurality of data pads, while adjusting a number of bits of data output from cell groups sharing activated sub-word line drivers.

In accordance with yet another embodiment of the present disclosure, a memory system includes a memory module including a plurality of memory devices; and a memory controller configured to provide a command and an address to control the memory module, and output and receive data to and from the memory module, wherein at least one of the plurality of memory devices includes: a memory cell array including a plurality of cell blocks, each block including a plurality of memory cells and sharing sub-word line drivers with adjacent cell blocks; a data input/output circuit configured to input and output the data of the plurality of cell blocks through a plurality of data pads; and a mapping circuit disposed between the memory cell array and the data input/output circuit, and configured to control a mapping between the plurality of cell blocks and the plurality of data pads, while adjusting, according to an output control signal, a number of bits of data output from cell blocks sharing activated sub-word line drivers.

According to embodiments of the present disclosure, the memory device may prevent the occurrence of an uncorrectable error (UE) and maximize the error correction capability by limiting the maximum number of error bits that may be caused by a fault of a sub-word line driver, within the error correction capability of the memory controller.

According to embodiments of the present disclosure, the memory device may provide optimized reliability, accessibility, and serviceability (RAS) operation by increasing the error relief capability of the memory controller.

These and other features and advantages of the embodiments of the present disclosure will become apparent to those skilled in the art from the following detailed description in conjunction with the following drawings.

### BRIEF DESCRIPTION OF THE DRAWINGS

FIG. 1 is a block diagram illustrating a memory system according to an embodiment of the present disclosure.

FIG. 2 is a diagram illustrating a data input/output operation of a memory device of FIG. 1.

FIG. 3 is a block diagram illustrating a memory device of FIG. 1 according to a first embodiment of the present disclosure.

FIGS. 4A and 4B are diagrams illustrating a memory cell array of FIG. 3 according to an embodiment of the present disclosure.

FIG. 5 is a diagram illustrating the memory cell array illustrated in FIGS. 4A and 4B, and a mapping circuit.

FIG. 6 is a table for describing an operation of an output control circuit according to an embodiment of the present disclosure.

FIGS. 7A and 7B are diagrams for describing an operation of the mapping circuit according to an output control signal described in FIG. 6.

FIG. 8 is a table for describing an operation of an output control circuit according to another embodiment of the present disclosure.

FIGS. 9A and 9B are diagrams for describing an operation of the mapping circuit according to an output control signal described in FIG. 8.

FIGS. 10A to 10B are diagrams illustrating a memory cell array of FIG. 3 according to another embodiment of the present disclosure.

FIG. 11 is a diagram illustrating the memory cell array illustrated in FIGS. 10A and 10B, and a mapping circuit.

FIG. 12 is a table for describing an operation of an output control circuit according to another embodiment of the present disclosure.

FIGS. 13A and 13B are diagrams for describing an operation of the mapping circuit according to an output control signal described in FIG. 12.

FIG. 14 is a block diagram illustrating a memory device of FIG. 1 according to a second embodiment of the present disclosure.

FIG. 15 is a table for describing an operation of a mapping control circuit of FIG. 14.

FIG. 16 is a block diagram illustrating a memory system including a memory module according to an embodiment of the present disclosure.

FIG. 17 is a block diagram illustrating a memory system including a stacked memory device according to an embodiment of the present disclosure.

FIG. 18 is a block diagram illustrating a mobile system including a memory device according to an embodiment of the present disclosure.

### DETAILED DESCRIPTION

Various embodiments of the present disclosure will be described below in more detail with reference to the accompanying drawings. The embodiments of the present disclosure may, however, be in different forms and should not be construed as limited to the embodiments set forth herein. Rather, these embodiments are provided so that this disclosure will be thorough and complete, and will fully convey the scope of the present disclosure to those skilled in the art. Throughout this disclosure, like reference numerals refer to like parts throughout the various figures and embodiments of the present disclosure.

It will be understood that when an element is referred to as being “coupled” or “connected” to another element, it may mean that the two are directly coupled or the two are electrically connected to each other with another circuit intervening therebetween. It will be further understood that the terms “comprise”, “include”, “have”, etc. when used in this specification, specify the presence of stated features, numbers, steps, operations, elements, components, and/or combinations of them but do not preclude the presence or addition of one or more other features, numbers, steps, operations, elements, components, and/or combinations thereof. In the present disclosure, the singular forms are intended to include the plural forms as well, unless the context clearly indicates otherwise.

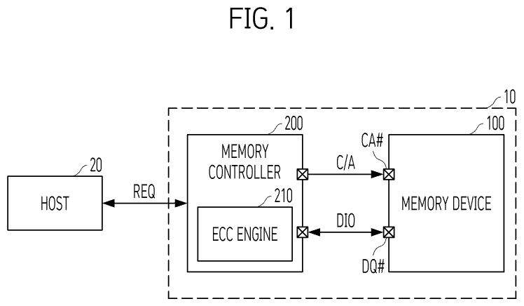

FIG. 1 is a block diagram illustrating a memory system 10 according to an embodiment of the present disclosure.

Referring to FIG. 1, the memory system 10 may include a memory device 100 and a memory controller 200. The memory system 10 may store data under the control of a host 20, such as a cellular phone, a smartphone, an MP3 player, a laptop computer, a desktop computer, a game player, a TV, a tablet PC, or an in-vehicle infotainment system. The host 20 may be an external device of the memory system 10.

The memory controller 200 may control operations of the memory system 10 and control data transfer between the host 20 and the memory device 100. The memory controller 200 may generate a command/address signal C/A according to a request REQ from the host 20 and provide the generated command/address signal C/A to the memory device 100. According to an embodiment, the memory controller 200 may provide a clock together with the command/address signal C/A. The memory controller 200 may provide data DIO corresponding to the request REQ from the host 20 to the memory device 100, and provide the data DIO read from the memory device 100 to the host 20. For example, the memory controller 200 may provide a write command, address, and data to the memory device 100 during a write operation. During a read operation, the memory controller 200 may provide a read command and address to the memory device 100 and provide data read from the memory device 100 to the host 20.

The memory controller 200 may include an error correction code (ECC) engine 210. The ECC engine 210 may detect and correct an error in the data DIO read from the memory device 100 and provide error-corrected data to the host 20. When the number of error bits of the data DIO exceeds an error correction capability of the ECC engine 210, the memory controller 200 may notify the host 20 that an uncorrectable error (UE) has occurred.

The memory device 100 may store the data DIO. The memory device 100 may operate under the control of the memory controller 200. The memory device 100 may include a memory cell array including a plurality of memory cells that store data. The memory device 100 may include dynamic random access memory (DRAM) including dynamic memory cells. In an embodiment, the memory device 100 may be a double data rate synchronous dynamic random access memory (DDR SDRAM), a low power double data rate (LPDDR) type SDRAM, a graphics double data rate (GDDR) SDRAM, a Rambus dynamic random access memory (RDRAM), or others.

The memory device 100 is configured to receive the command/address signal C/A from the memory controller 200 to access an area selected from the memory cell array. That is, the memory device 100 may perform an operation instructed by a command on the area selected by an address. For example, the memory device 100 may perform a write operation (e.g., program operation) to write data DIO to the area selected by the address. During a read operation, the memory device 100 may read data DIO from the area selected by the address.

In memory device 100, command/address pads CA #for receiving the command/address signal C/A and data pads DQ #for receiving the data DIO may be disposed. Although only one command/address pad CA #and one data pad DQ #are illustrated in FIG. 1, the command/address pads CA #and the data pads DQ #may be disposed in a number corresponding to the number of bits of the command/address signal C/A and the data DIO, respectively.

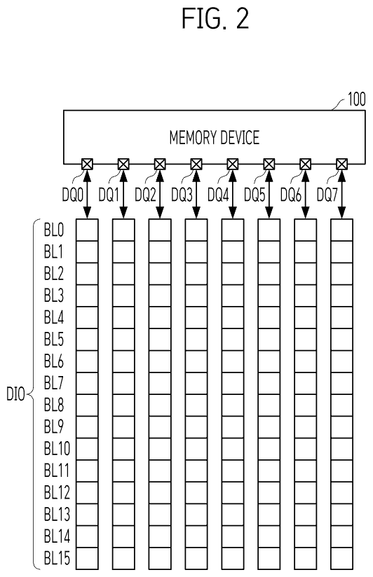

FIG. 2 is a diagram illustrating a data input/output operation of the memory device 100 of FIG. 1.

Referring to FIG. 2, the memory device 100 may use a number of data pads (i.e., the first to eighth data pads DQ0 to DQ7) corresponding to a data bus width to input/output data DIO according to a preset data width option (e.g., 8-bits). In addition, the memory device 100 may perform a burst operation for converting data outputted from the memory cell array in parallel into a serial order, and outputting the converted data during a preset burst length (e.g., 16).

Accordingly, the memory device 100 of FIG. 2 may input/output the data DIO of 8*16=128 bits during a single read operation or write operation by inputting/outputting data in units of 8-bits through the first to eighth data pads DQ0 to DQ7 during each of the burst lengths BL0 to BL15.

The memory device 100 of FIG. 2 illustrates a case where the data width option is set to 8 and the burst length is set to 16, and however the embodiments are not limited thereto. Various bit numbers of data may be input and output according to the setting of the data width option and the burst length.

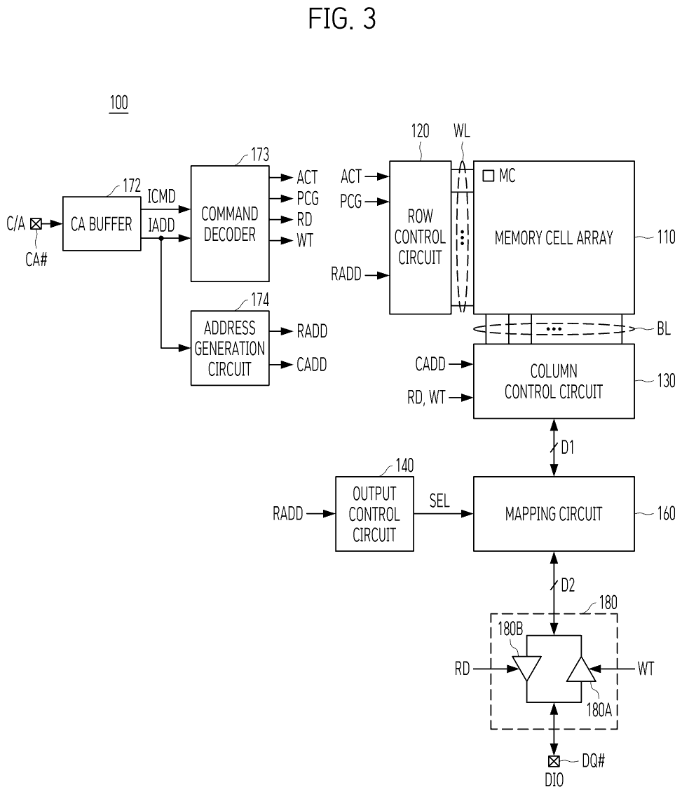

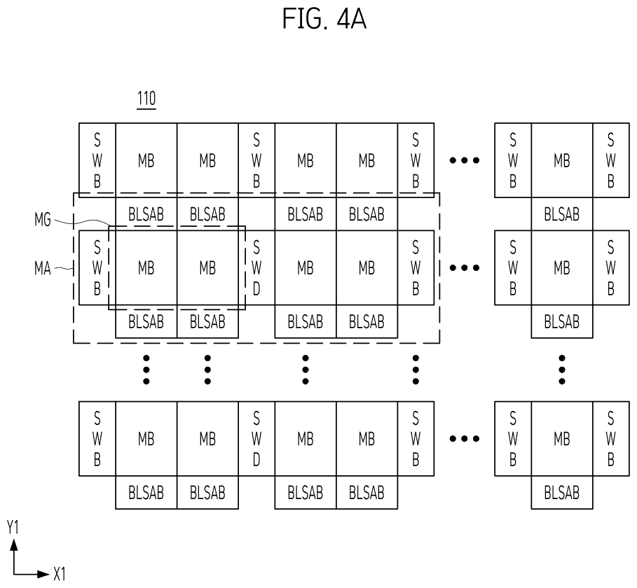

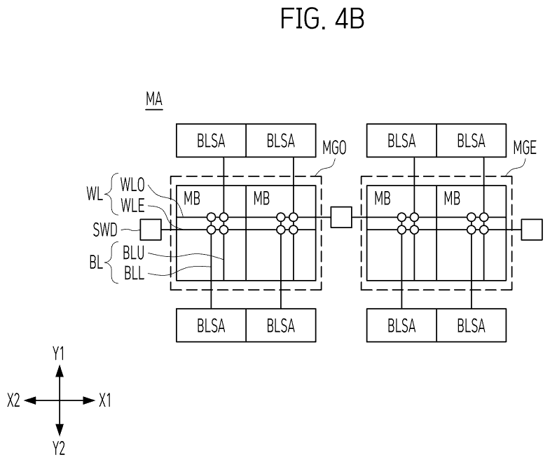

FIG. 3 is a block diagram illustrating the memory device 100 of FIG. 1 according to a first embodiment of the present disclosure. FIGS. 4A and 4B are diagrams illustrating a memory cell array 110 of FIG. 3 according to an embodiment of the present disclosure.

Referring to FIG. 3, the memory device 100 may include the memory cell array 110, a row control circuit 120, a column control circuit 130, an output control circuit 140, a mapping circuit 160, a command/address (CA) buffer 172, a command decoder 173, an address generation circuit 174, and a data input/output circuit 180.

The memory cell array 110 may be coupled to the row control circuit 120 through a plurality of word lines WL, and may be coupled to the column control circuit 130 through a plurality of bit lines BL. The plurality of word lines WL may extend in a first direction (e.g., a row direction) and are sequentially arranged in a second direction (e.g., a column direction). The plurality of bit lines BL may extend in a column direction and are sequentially arranged in a row direction. The memory cell array 110 may include a plurality of memory blocks (hereinafter, referred to as “cell blocks”), each including the plurality of memory cells MCs, respectively.

Referring to FIG. 4A, the memory cell array 110 may include a plurality of cell blocks MB arranged in an array form in a first direction X1 and a second direction Y1 intersecting the first direction X1. Each cell block MB may include a plurality of memory cells MC connected between a plurality of word lines WL and a plurality of bit lines BL. In an embodiment of the present disclosure, the “cell block” may be defined as a set of memory cells that share the word lines WL and the bit lines BL and are arranged in the same form.

In the embodiment of FIG. 4A, two adjacent cell blocks among the cell blocks MB disposed in the first direction X1 may form one cell group MG. That is, the cell blocks MB disposed in the first direction X1 may be grouped into a plurality of cell groups MG. Sub-word line driver regions SWB may be arranged between cell blocks MB disposed in the first direction X1. A plurality of sub-word line drivers may be disposed in the sub-word line driver region SWB. Bit line sense amplifier regions BLSAB may be arranged between cell blocks MB disposed in the second direction Y1. A plurality of bit line sense amplifiers may be disposed in the bit line sense amplifier region BLSAB.

Referring to FIG. 4B, a partial area MA including two cell groups MG of FIG. 4A is shown.

The squares between the cell groups MG may represent the sub-word line drivers SWD, and the lines extending to the left and right of the sub-word line drivers SWD may represent the word lines (or sub-word lines). In reality, a much larger number of sub-word line drivers SWD and word lines exist, but only a part of the lines are shown to illustrate the simple structure for illustrative purpose.

Each of the cell groups MG may include odd-numbered word lines (hereinafter, referred to as “first word lines WLO”) and even-numbered word lines (hereinafter, referred to as “second word lines WLE”) extending in the first direction X1 and alternating with each other in the second direction Y1. In odd-numbered cell groups MG0, the first word lines WLO may share sub-word line drivers SWD with an adjacent cell group disposed in the first direction X1, and the second word lines WLE may share sub-word line drivers SWD with an adjacent cell group disposed in a direction X2 opposite to the first direction X1. Conversely, in even-numbered cell groups MGE, the second word lines WLE may share sub-word line drivers SWD with an adjacent cell group disposed in the first direction X1, and the first word lines WLO may share sub-word line drivers SWD with an adjacent cell group disposed in the direction X2. That is, since two adjacent cell groups MG0 and MGE share the sub-word line drivers SWD, one sub-word line driver SWD may be allocated to four adjacent cell blocks MB disposed in the first direction X1.

Each of the cell blocks MB may include first bit lines BLU and second bit lines BLL extending in the second direction Y1 and alternately disposed in the first direction X1. The first bit lines BLU may share bit line sense amplifiers BLSA with an adjacent cell block disposed in the second direction Y1, and the second bit lines BLL may share bit line sense amplifiers BLSA with an adjacent cell block disposed in a direction Y2 opposite to the second direction Y1. That is, since two adjacent cell blocks MB disposed in the second direction Y1 share the bit line sense amplifiers BLSA, one bit line sense amplifier BLSA may be allocated to two adjacent cell blocks MB disposed in the second direction Y1.

Referring back to FIG. 3, the row control circuit 120 may perform an active operation of activating a word line selected by a row address RADD in response to an active command ACT, and perform a precharge operation of precharging the activated word line in response to a precharge command PCG.

The column control circuit 130 may select some bit lines of the bit lines BL of the memory cell array 110 according to a column address CADD, perform a read operation of reading data D1 from the memory cells MC through the selected bit lines in response to a read command RD, or perform a write operation of writing data D1 to the memory cells MC through the selected bit lines in response to a write command WT.

The CA buffer 172 may receive a command/address signal C/A through command/address pads CA #from an external device (e.g., the memory controller 200 of FIG. 1). The CA buffer 172 may buffer the command/address signal C/A to output an internal command ICMD and an internal address IADD.

The command decoder 173 may decode the internal command ICMD to generate the active command ACT, the precharge command PCG, the write command WT, the read command RD, and the like. The active command ACT is a signal input when an active operation is instructed, the precharge command PCG is a signal input when a precharge operation is instructed, the write command WT is a signal input when a write operation is instructed, and the read command RD may be a signal input when a read operation is instructed.

The address generation circuit 174 may classify the internal address IADD received from the command decoder 173 into the row address RADD and the column address CADD. The row address RADD may be an address for selecting one of the plurality of word lines WL, and the column address CADD may be an address for selecting some bit lines on which a read operation and a write operation are to be performed among the plurality of bit lines BL. Each of the row address RADD and the column address CADD may include multiple bits. According to an embodiment, the address generation circuit 174 may classify some bits of the internal address IADD into a row address RADD, and classify the remaining bits into a column address CADD. Alternatively, the address generation circuit 174 may classify the address into a row address RADD when an active operation is instructed as a result of decoding the command decoder 173, and classify the address as a column address CADD when a read and write operation is instructed.

According to an embodiment, the memory cell array 110 may include a plurality of banks (not shown). When the memory cell array 110 is formed of a plurality of banks, the row control circuit 120 and the column control circuit 130 may be arranged in a number corresponding to the number of banks. The address generation circuit 174 may classify the internal address IADD into a bank address, a row address RADD, and a column address CADD, and one bank among the plurality of banks may be specified by the bank address. The number of banks or the number of memory cells MC may be determined according to the capacity of the memory device 100.

The output control circuit 140 may generate an output control signal SEL based on at least one bit of the row address RADD. For example, the output control circuit 140 may generate the output control signal SEL having one or more bits of which a logic level is determined according to a least significant bit (LSB) RADD<0> of the row address RADD.

The mapping circuit 160 may be disposed between the column control circuit 130 and the data input/output circuit 180 to control a mapping between the memory cell array 110 and the plurality of data pads DQ #. According to the output control signal SEL, the mapping circuit 160 may map (i.e., allocate) the data D1 outputted from the plurality of cell blocks MB, into data D2, or map the data D2 transmitted from the data input/output circuit 180 into the data D1 to be written to the plurality of cell blocks MB. For example, the mapping circuit 160 may map 256-bit data D1 outputted from the memory cell array 110 to 128-bit data D2 during a read operation. In an embodiment of the present disclosure, the mapping circuit 160 may adjust the number of bits of data output from cell blocks sharing the sub-word line drivers SWD, among the plurality of cell blocks MB, according to the output control signal SEL. For example, when four cell blocks share one sub-word line driver, as described in FIG. 4B, the mapping circuit 160 may map only data D1 output from two cell blocks among the four cell blocks sharing the sub-word line driver, into the data D2.

The data input/output circuit 180 may receive data DIO from the memory controller 200, or transmit data DIO to the memory controller 200, through the data pads DQ #. The data input/output circuit 180 may include a data input circuit 180A and a data output circuit 180B. The data input circuit 180A may receive the data DIO from the memory controller 200 as the data D2, according to the write command WT. The data input circuit 180A may transmit the data D2 by converting the data DIO that are input with a burst length 16 through each of the data pads DQ #in parallel. The data output circuit 180B may transmit the data D2 read from the memory cell array 110 as the data DIO to the memory controller 200, according to the read command RD. The data output circuit 180B may transmit the data DIO by converting the data D2 to the burst length 16 in series. Although the data input/output circuit 180 is illustrated as one configuration in FIG. 3, the data input/output circuit 180 may include a number of data input/output units corresponding to the number of the data pads DQ #.

As described in FIG. 4B, since adjacent cell groups among the plurality of cell groups MG share the sub-word line drivers SWD, one sub-word line driver SWD may take charge of four cell blocks MB disposed in the first direction X1. Accordingly, when a failure occurs in one sub-word line driver SWD, error bits may simultaneously occur in four cell blocks on both sides of the sub-word line driver. For example, when 8-bit data is output per cell block, when a failure occurs in one sub-word line driver SWD, error bits of up to 32 bits may occur. In this case, when the ECC engine 210 of the memory controller 200 has the error correction capability for 16-bits, an uncorrectable error (UE) may occur.

In an embodiment of the present disclosure, the mapping circuit 160 may change a mapping between cell blocks and data pads according to the output control signal SEL so that the number of bits of data output from cell blocks sharing the sub-word line drivers SWD is reduced. Accordingly, the memory device 100 may prevent the occurrence of the uncorrectable error (UE) by limiting the maximum number of error bits that may be caused by the fault of the sub-word line driver to within the error correction capability of the memory controller 200.

Hereinafter, specific embodiments of the present disclosure will be described with reference to the drawings.

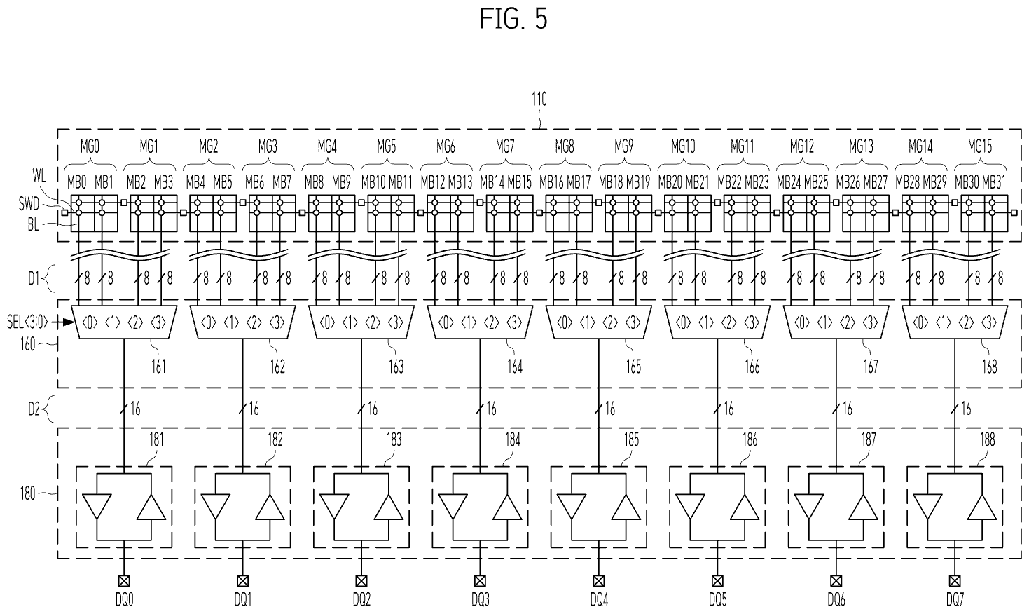

FIG. 5 is a diagram illustrating the memory cell array 110 illustrated in FIGS. 4A and 4B, and the mapping circuit 160. For convenience of description, a configuration of the column control circuit 130 for selecting the bit lines BL is omitted.

Referring to FIG. 5, the memory cell array 110 including first to 32nd cell blocks MB0 to MB31 disposed in the first direction is illustrated. Since two adjacent cell blocks form one cell group, the first to 32nd cell blocks MB0 to MB31 may constitute first to 16th cell groups MG0 to MG15.

As described above, each of the cell groups MG0 to MG15 may alternately share sub-word line drivers SWD with adjacent cell groups. Since 16 cell groups are arranged, eight or nine sub-word line drivers SWD may be arranged at the same level in the first direction. One sub-word line driver SWD may be allocated to four cell blocks MB disposed in the first direction.

During a read operation or write operation, each of the cell blocks MB0 to MB31 may input and output data in units of 8-bits. That is, each of the cell blocks MB0 to MB31 may read 8-bit data from selected memory cells connected between a word line designated by a row address and a predetermined number (e.g., 8) of bit lines designated by a column address, or write 8-bit data to the selected memory cells. All sub-word line drivers SWD positioned at the same level in the first direction may be activated to select a word line designated by a row address.

The mapping circuit 160 may include first to eighth mappers 161 to 168, each of which corresponds to four cell blocks included in two adjacent cell groups. For example, the first mapper 161 may correspond to the first to fourth cell blocks MB0 to MB3. The first to eighth mappers 161 to 168 may transmit the data D2 to the data input/output circuit 180 by mapping the data D1 output from the first to 32nd cell blocks MB0 to MB31, into the data D2, or transmit the data D1 to the first to 32nd cell blocks MB0 to MB31 by mapping the data D2 transmitted from the data input/output circuit 180, into the data D1.

The data input/output circuit 180 may include first to eighth data input/output units 181 to 188 corresponding to the first to eighth mappers 161 to 168 and the first to eighth data pads DQ0 to DQ7, respectively. Each of the data input/output units 181 to 188 may receive the data DIO from the memory controller 200 through a corresponding data pad, and transmit the data D2 transmitted from the corresponding mapper to the memory controller 200 through the corresponding data pad.

In an embodiment of the present disclosure, the output control circuit 140 may generate an output control signal SEL<3:0> composed of four bits, while controlling two of the four bits of the output control signal SEL<3:0> to be set to a high bit. Accordingly, each mapper may select two cell blocks among the four cell blocks, according to the output control signal SEL<3:0> during a read operation, and may receive 8-bit data D1 output from each of the selected cell blocks to output 16-bit data D2 to the data input/output circuit 180. Each mapper may select two cell blocks among the four cell blocks, according to the output control signal SEL<3:0> during a write operation, and may receive 16-bit data D2 from the data input/output circuit 180 to output 8-bit data D1 to each of the selected cell blocks.

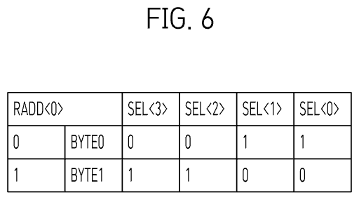

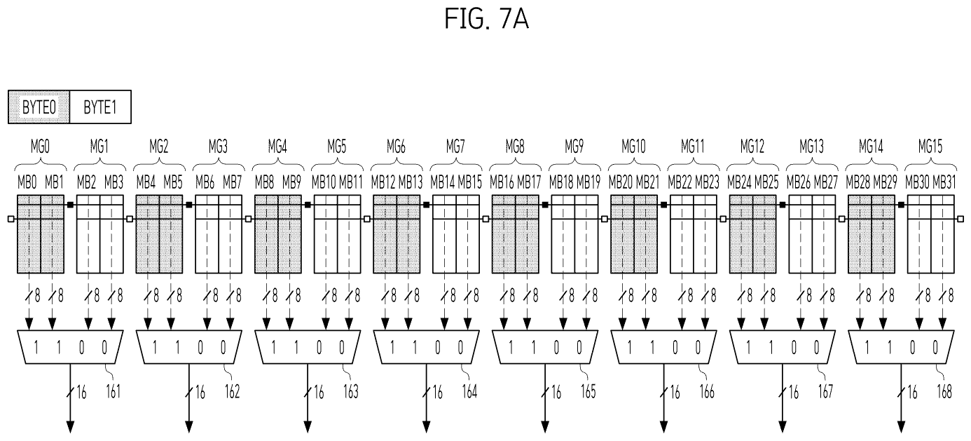

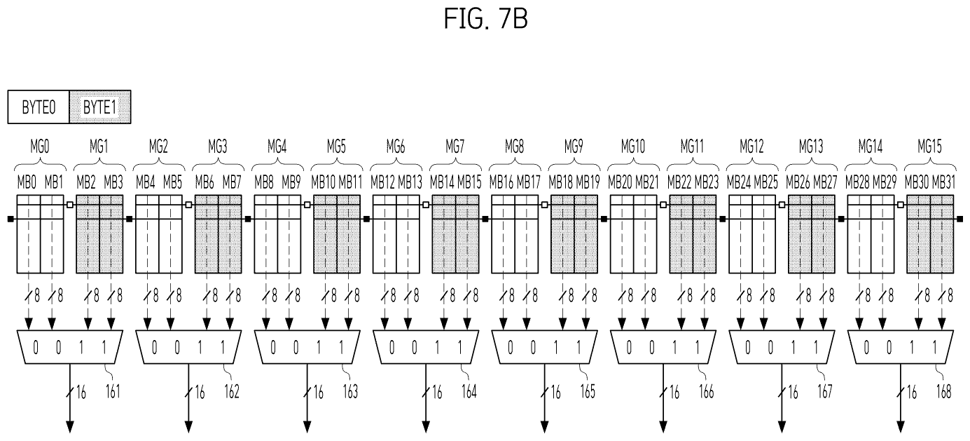

FIG. 6 is a table for describing an operation of the output control circuit 140 according to an embodiment of the present disclosure. FIGS. 7A and 7B are diagrams for describing an operation of the mapping circuit 160 according to the output control signal SEL<3:0> described in FIG. 6. For convenience of description, an operation of the mapping circuit 160 during a read operation will be described.

Referring to FIG. 6, the output control circuit 140 may generate the output control signal SEL<3:0> of “0011” when the LSB RADD<0> of the row address RADD is set to a low bit (referred to as “BYTE0”), and generate the output control signal SEL<3:0> of “1100” when the LSB RADD<0> is set to a high bit (referred to as “BYTE1”).

Referring to FIG. 7A, when the LSB RADD<0> of the row address RADD is a low bit (BYTE0), sub-word line drivers SWD may be activated to select odd-numbered word lines (i.e., “first word lines WLO”). The activated sub-word line drivers SWD are denoted as a black box in FIG. 7A. The mapping circuit 160 may select data of cell blocks included in odd-numbered cell groups according to the output control signal SEL<3:0> of “0011”, to transmit the selected data to the data input/output circuit 180. In more detail, the first mapper 161 may select data of the first and second cell blocks MB0 and MB1 included in the first cell group MG0, among the first to fourth cell blocks MB0 to MB3. The second mapper 162 may select data of the fifth and sixth cell blocks MB4 and MB5 included in the third cell group MG2, among the fifth to eighth cell blocks MB4 to MB7. In this way, the eighth mapper 168 may select data of the 29th and 30th cell blocks MB28 and MB29 included in the 15th cell group MG14, among the 29th to 32nd cell blocks MB28 to MB31. As a result, when the LSB RADD<0> of the row address RADD is a low bit (BYTE0), 128-bit data D2 may be output from cell blocks included in odd-numbered cell groups.

Referring to FIG. 7B, when the LSB RADD<0> of the row address RADD is a high bit (BYTE1), sub-word line drivers SWD may be activated to select even-numbered word lines (i.e., “second word lines WLE”). The activated sub-word line drivers SWD are denoted as a black box in FIG. 7B. The mapping circuit 160 may select data of cell blocks included in even-numbered cell groups according to the output control signal SEL<3:0> of “1100”, to transmit the selected data to the data input/output circuit 180. In more detail, the first mapper 161 may select data of the third and fourth cell blocks MB2 and MB3 included in the second cell group MG1, among the first to fourth cell blocks MB0 to MB3. The second mapper 162 may select data of the seventh and eighth cell blocks MB6 and MB7 included in the fourth cell group MG3, among the fifth to eighth cell blocks MB4 to MB7. In this way, the eighth mapper 168 may select data of the 31st and 32nd cell blocks MB30 and MB31 included in the 16th cell group MG15, among the 29th to 32nd cell blocks MB28 to MB31. As a result, when the LSB RADD<0> of the row address RADD is a high bit (BYTE1), 128-bit data D2 may be output from cell blocks included in even-numbered cell groups.

As described above, the mapping circuit 160 may map the data output from the cell blocks included in one of two cell groups sharing the sub-word line drivers, into the data pads.

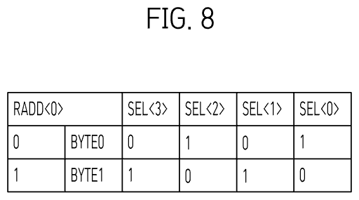

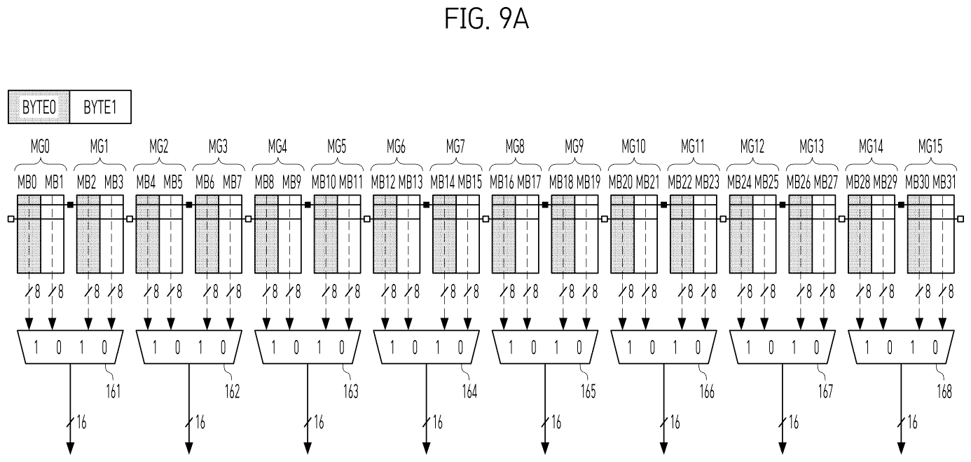

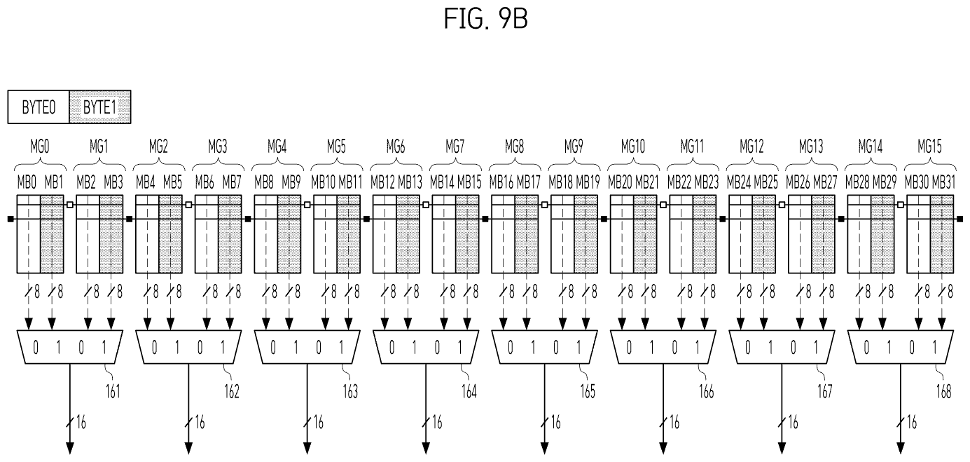

FIG. 8 is a table for describing an operation of the output control circuit 140 according to another embodiment of the present disclosure. FIGS. 9A and 9B are diagrams for describing an operation of the mapping circuit 160 according to the output control signal SEL<3:0> described in FIG. 8. For convenience of description, an operation of the mapping circuit 160 during a read operation will be described.

Referring to FIG. 8, the output control circuit 140 may generate the output control signal SEL<3:0> of “0101” when the LSB RADD<0> of the row address RADD is set to a low bit (referred to as “BYTE0”), and generate the output control signal SEL<3:0> of “1010” when the LSB RADD<0> is set to a high bit (referred to as “BYTE1”).

Referring to FIG. 9A, when the LSB RADD<0> of the row address RADD is a low bit (BYTE0), sub-word line drivers SWD may be activated to select odd-numbered word lines (i.e., “first word lines WLO”). The activated sub-word line drivers SWD are denoted as a black box in FIG. 9A. The mapping circuit 160 may select data of an odd-numbered cell block included in each cell group according to the output control signal SEL<3:0> of “0101”, to transmit the selected data to the data input/output circuit 180. In more detail, the first mapper 161 may select data of the first cell block MB0 included in the first cell group MG0 and data of the third cell block MB2 included in the second cell group MG1, among the first to fourth cell blocks MB0 to MB3. The second mapper 162 may select data of the fifth cell block MB4 included in the third cell group MG2 and data of the seventh cell block MB6 included in the fourth cell group MG3, among the fifth to eighth cell blocks MB4 to MB7. In this way, the eighth mapper 168 may select data of the 29th cell block MB28 included in the 15th cell group MG14 and data of the 31st cell block MB30 included in the 16th cell group MG15, among the 29th to 32nd cell blocks MB28 to MB31. As a result, when the LSB RADD<0> of the row address RADD is a low bit (BYTE0), 128-bit data D2 may be output from odd-numbered cell blocks.

Referring to FIG. 9B, when the LSB RADD<0> of the row address RADD is a high bit (BYTE1), sub-word line drivers SWD may be activated to select even-numbered word lines (i.e., “second word lines WLE”). The activated sub-word line drivers SWD are denoted as a black box in FIG. 9B. The mapping circuit 160 may select data of an even-numbered cell block included in each cell group according to the output control signal SEL<3:0> of “1010”, to transmit the selected data to the data input/output circuit 180. In more detail, the first mapper 161 may select data of the second cell block MB1 included in the first cell group MG0 and data of the fourth cell block MB3 included in the second cell group MG1, among the first to fourth cell blocks MB0 to MB3. The second mapper 162 may select data of the sixth cell block MB5 included in the third cell group MG2 and data of the eighth cell block MB7 included in the fourth cell group MG3, among the fifth to eighth cell blocks MB4 to MB7. In this way, the eighth mapper 168 may select data of the 30th cell block MB29 included in the 15th cell group MG14 and data of the 32nd cell block MB31 included in the 16th cell group MG15, among the 29th to 32nd cell blocks MB28 to MB31. As a result, when the LSB RADD<0> of the row address RADD is a high bit (BYTE1), 128-bit data D2 may be output from even-numbered cell blocks.

As described above, the mapping circuit 160 may map the data output from the cell block included in each of two cell groups sharing the sub-word line drivers, into the data pads.

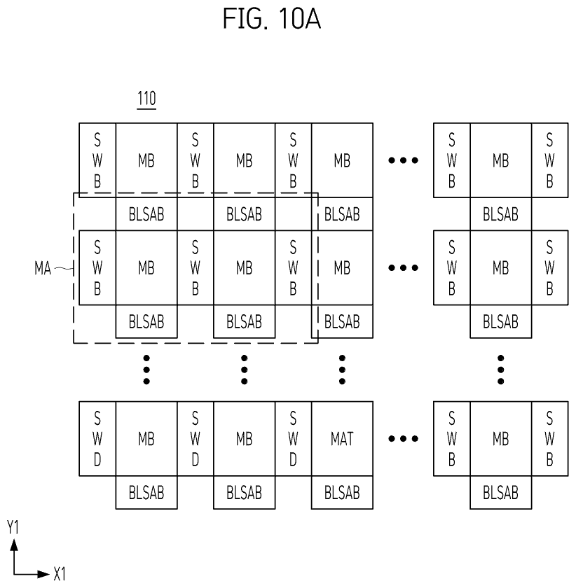

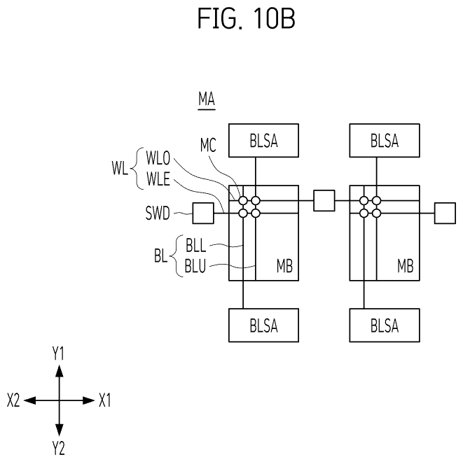

FIGS. 10A to 10B are diagrams illustrating the memory cell array 110 of FIG. 3 according to another embodiment of the present disclosure.

Referring to FIG. 10A, the memory cell array 110 may include a plurality of cell blocks MB arranged in an array form in a first direction X1 and a second direction Y1 intersecting the first direction X1. Each cell block MB may include a plurality of memory cells MC connected between a plurality of word lines WL and a plurality of bit lines BL.

In the embodiment of FIG. 10A, sub-word line driver regions SWB may be arranged between cell blocks MB disposed in the first direction X1. A plurality of sub-word line drivers may be disposed in the sub-word line driver region SWB. Bit line sense amplifier regions BLSAB may be arranged between cell blocks MB disposed in the second direction Y1. A plurality of bit line sense amplifiers may be disposed in the bit line sense amplifier region BLSAB.

Referring to FIG. 10B, a partial area MA of FIG. 10A is shown.

The squares between the cell blocks MB may represent the sub-word line drivers SWD, and the lines extending to the left and right of the sub-word line drivers SWD may represent the word lines (or sub-word lines). In reality, a much larger number of sub-word line drivers SWD and word lines exist, but only a part of the lines are shown to illustrate the simple structure for illustrative purpose.

Each of the cell blocks MB may include odd-numbered word lines (hereinafter, referred to as “first word lines WLO”) and even-numbered word lines (hereinafter, referred to as “second word lines WLE”) extending in the first direction X1 and alternating with each other in the second direction Y1. In odd-numbered cell blocks MB, the first word lines WLO may share sub-word line drivers SWD with an adjacent cell block disposed in the first direction X1, and the second word lines WLE may share sub-word line drivers SWD with an adjacent cell block disposed in a direction X2 opposite to the first direction X1. Conversely, in even-numbered cell blocks MB, the second word lines WLE may share sub-word line drivers SWD with an adjacent cell block disposed in the first direction X1, and the first word lines WLO may share sub-word line drivers SWD with an adjacent cell block disposed in the direction X2. That is, since two adjacent cell blocks MB disposed in the first direction X1 share the sub-word line drivers SWD, one sub-word line driver SWD may be allocated to two adjacent cell blocks MB disposed in the first direction X1.

Each of the cell blocks MB may include first bit lines BLU and second bit lines BLL extending in the second direction Y1 and alternately disposed in the first direction X1. The first bit lines BLU may share bit line sense amplifiers BLSA with an adjacent cell block disposed in the second direction Y1, and the second bit lines BLL may share bit line sense amplifiers BLSA with an adjacent cell block disposed in a direction Y2 opposite to the second direction Y1. That is, since two adjacent cell blocks MB disposed in the second direction Y1 share the bit line sense amplifiers BLSA, one bit line sense amplifier BLSA may be allocated to two adjacent cell blocks MB disposed in the second direction Y1.

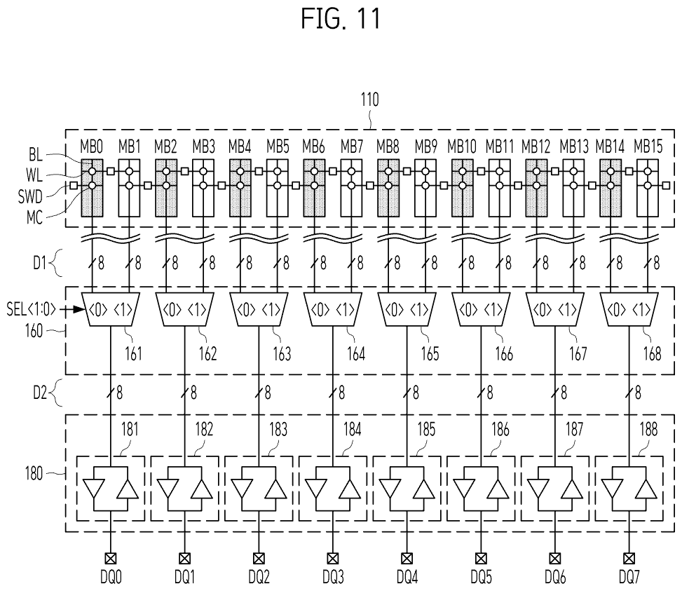

FIG. 11 is a diagram illustrating the memory cell array 110 illustrated in FIGS. 10A and 10B, and the mapping circuit 160. For convenience of description, a configuration of the column control circuit 130 for selecting the bit lines BL is omitted.

Referring to FIG. 11, the memory cell array 110 including first to 16th cell blocks MB0 to MB15 disposed in the first direction is illustrated.

As described above, each of the cell blocks MB0 to MB15 may alternately share sub-word line drivers SWD with adjacent cell blocks. Since 16 cell blocks are arranged, eight or nine sub-word line drivers SWD may be arranged at the same level in the first direction. One sub-word line driver SWD may be allocated to two cell blocks MB disposed in the first direction.

During a read operation or write operation, each of the cell blocks MB0 to MB15 may input and output data in units of 8-bits. That is, each of the cell blocks MB0 to MB15 may read 8-bit data from selected memory cells connected between a word line designated by a row address and a predetermined number (e.g., 8) bit lines designated by a column address, or write 8-bit data to the selected memory cells. All sub-word line drivers SWD positioned at the same level in the first direction may be activated to select a word line designated by a row address.

The mapping circuit 160 may include first to eighth mappers 161 to 168, each of which corresponds to two adjacent cell blocks. For example, the first mapper 161 may correspond to the first and second cell blocks MB0 and MB1. The first to eighth mappers 161 to 168 may transmit the data D2 to the data input/output circuit 180 by mapping the data D1 output from the first to 16th cell blocks MB0 to MB15, into the data D2, or transmit the data D1 to the first to 16th cell blocks MB0 to MB15 by mapping the data D2 transmitted from the data input/output circuit 180, into the data D1.

In an embodiment of the present disclosure, the output control circuit 140 may generate an output control signal SEL<1:0> composed of two bits, while controlling one of the two bits of the output control signal SEL<1:0> to be set to a high bit. Accordingly, each mapper may select one cell block among the two cell blocks, according to the output control signal SEL<1:0> during a read operation, and may receive 8-bit data D1 output from the selected cell block to output 8-bit data D2 to the data input/output circuit 180. Each mapper may select one cell block among the two cell blocks, according to the output control signal SEL<1:0> during a write operation, and may receive 8-bit data D2 from the data input/output circuit 180 to output 8-bit data D1 to the selected cell block.

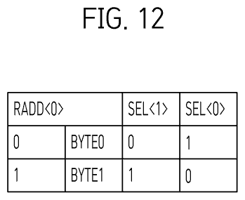

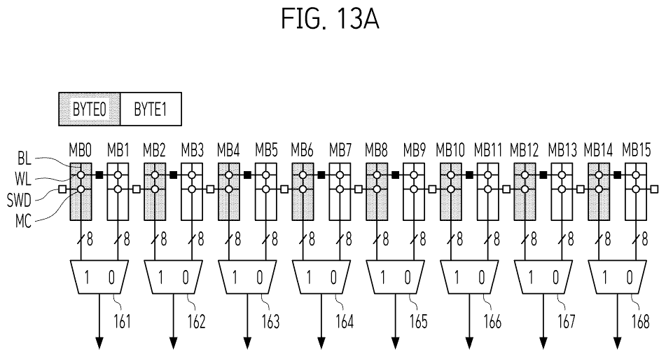

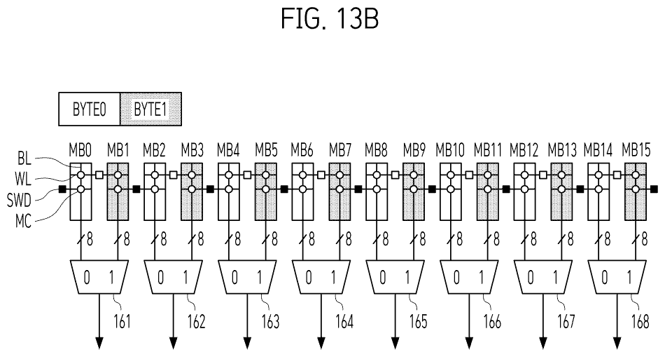

FIG. 12 is a table for describing an operation of the output control circuit 140 according to another embodiment of the present disclosure. FIGS. 13A and 13B are diagrams for describing an operation of the mapping circuit 160 according to the output control signal SEL<1:0> described in FIG. 12. For convenience of description, an operation of the mapping circuit 160 during a read operation will be described.

Referring to FIG. 12, the output control circuit 140 may generate the output control signal SEL<1:0> of “01” when the LSB RADD<0> of the row address RADD is set to a low bit (referred to as “BYTE0”), and generate the output control signal SEL<1:0> of “10” when the LSB RADD<0> is set to a high bit (referred to as “BYTE1”).

Referring to FIG. 13A, when the LSB RADD<0> of the row address RADD is a low bit (BYTE0), sub-word line drivers SWD may be activated to select odd-numbered word lines (i.e., “first word lines WLO”). The activated sub-word line drivers SWD are denoted as a black box in FIG. 13A. The mapping circuit 160 may select data of odd-numbered cell blocks according to the output control signal SEL<1:0> of “01”, to transmit the selected data to the data input/output circuit 180. As a result, when the LSB RADD<0> of the row address RADD is a low bit (BYTE0), 64-bit data D2 may be output from odd-numbered cell blocks.

Referring to FIG. 13B, when the LSB RADD<0> of the row address RADD is a high bit (BYTE1), sub-word line drivers SWD may be activated to select even-numbered word lines (i.e., “second word lines WLE”). The activated sub-word line drivers SWD are denoted as a black box in FIG. 13B. The mapping circuit 160 may select data of even-numbered cell blocks according to the output control signal SEL<1:0> of “10”, to transmit the selected data to the data input/output circuit 180. As a result, when the LSB RADD<0> of the row address RADD is a high bit (BYTE1), 64-bit data D2 may be output from even-numbered cell blocks.

As described above, the mapping circuit 160 may map the data output from one cell block among two cell blocks sharing the sub-word line drivers, into the data pads.

In the first embodiment, it has been described that the output control signal SEL is generated based on the row address RADD, but the embodiment is not limited thereto.

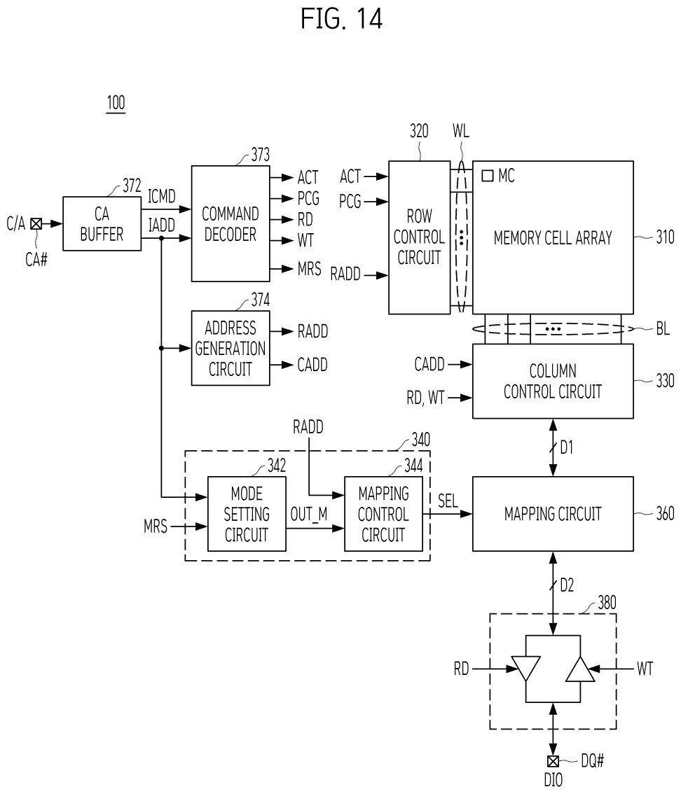

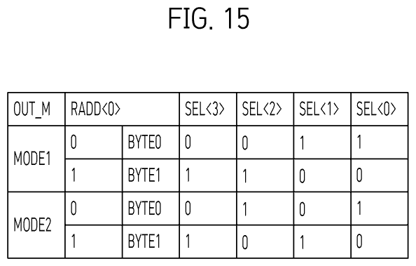

FIG. 14 is a block diagram illustrating the memory device 100 of FIG. 1 according to a second embodiment of the present disclosure. FIG. 15 is a table for describing an operation of a mapping control circuit 344 of FIG. 14.

Referring to FIG. 14, the memory device 100 may include a memory cell array 310, a row control circuit 320, a column control circuit 330, an output control circuit 340, a mapping circuit 360, a command/address (CA) buffer 372, a command decoder 373, an address generation circuit 374, and a data input/output circuit 380. The configuration and operation of the memory cell array 310, the row control circuit 320, the column control circuit 330, the mapping circuit 360, the CA buffer 372, the address generation circuit 374, and the data input/output circuit 380 are substantially the same as those of FIG. 3.

The command decoder 373 may decode an internal command ICMD output from the CA buffer 172 to further generate a mode setting command MRS in addition to an active command ACT, a precharge command PCG, a write command WT, a read command RD, and the like. The mode setting command MRS may include commands for storing and reading setting data stored in a mode setting circuit 342 included in the memory device 100.

The output control circuit 340 may generate mode information OUT_M for selecting one of a plurality of modes according to the mode setting command MRS, and generate an output control signal SEL based on the mode information OUT_M and a row address RADD.

In more detail, the output control circuit 340 may include the mode setting circuit 342 and the mapping control circuit 344.

The mode setting circuit 342 may perform various setting operations by decoding at least some bits of an internal address IADD output from the CA buffer 172, in response to the mode setting command MRS. The mode setting circuit 342 may be implemented as a known mode register set circuit. The mode setting circuit 342 may store the mode information OUT_M for selecting one from the plurality of modes, and provide the stored mode information OUT_M to the mapping control circuit 344 in response to the mode register command MRS.

The mapping control circuit 344 may generate the output control signal SEL based on the mode information OUT_M and the row address RADD.

Referring to FIG. 15, the mapping control circuit 344 may generate the output control signal SEL based on the row address RADD when the mode information OUT_M designates a first mode. For example, in the first mode “MODE1”, the mapping control circuit 344 may generate the output control signal SEL<3:0> of “0011” when a least significant bit (LSB) RADD<0> of the row address RADD is set to a low bit, and generate the output control signal SEL<3:0> of “1100” when the LSB RADD<0> is set to a high bit. In addition, the mapping control circuit 344 may generate the output control signal SEL based on the row address RADD when the mode information OUT_M designates a second mode. For example, in the second mode “MODE2”, the mapping control circuit 344 may generate the output control signal SEL<3:0> of “0101” when the LSB RADD<0> of the row address RADD is set to a low bit, and generate the output control signal SEL<3:0> of “1010” when the LSB RADD<0> of the row address RADD is set to a high bit.

An operation of the mapping circuit 360 in each mode according to the output control signal SEL<3:0> will be described as follows.

In the first mode, when the LSB RADD<0> of the row address RADD is a low bit (BYTE0), the sub-word line drivers SWD may be activated to select odd-numbered word lines. The mapping circuit 360 may select data of cell blocks included in odd-numbered cell groups according to the output control signal SEL<3:0> of “0011” and transmit the selected data to the data input/output circuit 380 (see FIG. 7A).

In the first mode, when the LSB RADD<0> of the row address RADD is a high bit (BYTE1), the sub-word line drivers SWD may be activated to select even-numbered word lines. The mapping circuit 360 may select data of cell blocks included in even-numbered cell groups according to the output control signal SEL<3:0> of “1100” and transmit the selected data to the data input/output circuit 380 (see FIG. 7B).

In the second mode, when the LSB RADD<0> of the row address RADD is a low bit (BYTE0), the sub-word line drivers SWD may be activated to select the odd-numbered word lines. The mapping circuit 360 may select data of an odd-numbered cell block included in each cell group according to the output control signal SEL<3:0> of “0101” and transmit the selected data to the data input/output circuit 380 (see FIG. 9A).

In the second mode, when the LSB RADD<0> of the row address RADD is a high bit (BYTE1), the sub-word line drivers SWD may be activated to select even-numbered word lines. The mapping circuit 360 may select data of an even-numbered cell block included in each cell group according to the output control signal SEL<3:0> of “1010” and transmit the selected data to the data input/output circuit 380 (see FIG. 9B).

As described above, in an embodiment of the present disclosure, the mapping circuit 360 may change a mapping between the cell blocks and the data pads according to the output control signal SEL so that the number of bits of data output from the cell blocks sharing the sub-word line drivers SWD is reduced. Accordingly, the memory device 100 may prevent the occurrence of an uncorrectable error (UE) by limiting the maximum number of error bits that may be caused by the fault of the sub-word line driver to within the error correction capability of the memory controller 200.

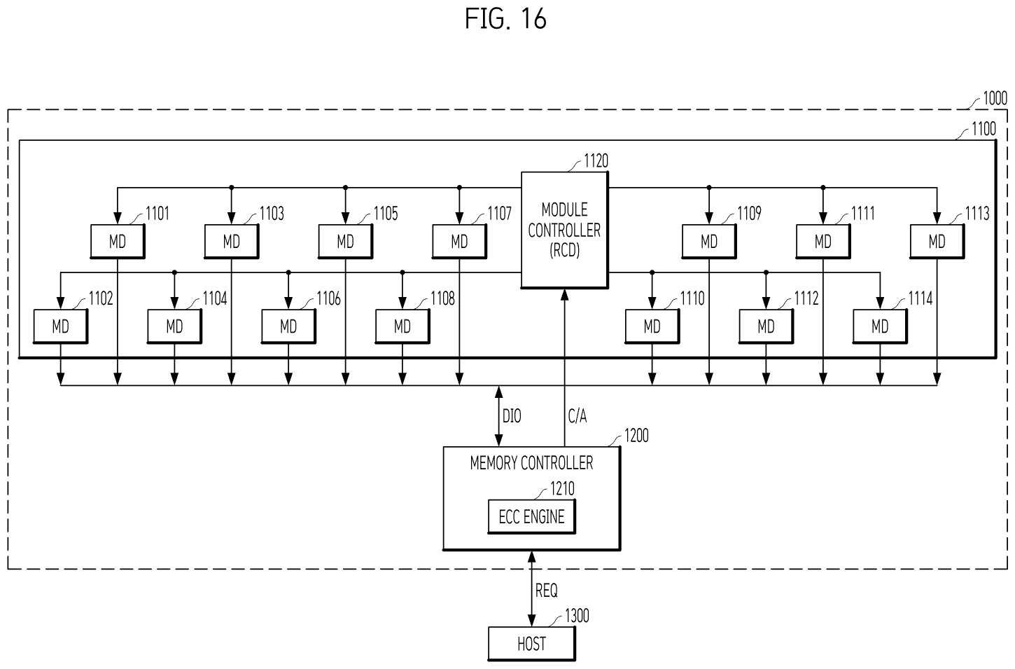

FIG. 16 is a block diagram illustrating a memory system 1000 including a memory module 1100 according to an embodiment of the present disclosure.

Referring to FIG. 16, the memory system 1000 may include the memory module 1100 and a memory controller 1200.

The memory controller 1200 may control operations of the memory system 1000 and control a data transfer between a host 1300 and the memory module 1100. The memory controller 1200 may generate a command/address signal C/A according to a request REQ from the host 1300 to provide the command/address signal C/A to the memory module 1100, and provide data DIO corresponding to the request REQ from the host 1300 to the memory module 1100, and provide data DIO read from the memory module 1100 to the host 1300.

The memory controller 1200 may include an error correction code (ECC) engine 1210. The ECC engine 1210 may detect and correct an error in the data DIO read from the memory device 100 and provide error-corrected data to the host 1300. When the number of error bits of the data DIO exceeds an error correction capability of the ECC engine 1210, the memory controller 1200 may notify the host 1300 that an uncorrectable error (UE) has occurred. The memory controller 1200 may correspond to the memory controller 200 of FIG. 1.

The memory module 1100 may include a plurality of memory devices (MD) 1101 to 1114 and a module controller (RCD) 1120. The module controller 1120 may include a known register clock driver. The module controller 1120 may control the memory devices 1101 to 1114 under the control of the memory controller 1200. For example, the module controller 1120 may receive the command/address signal C/A from the memory controller 1200 and control the data DIO to be written to the memory devices 1101 to 1114 or read from the memory devices 1101 to 1114.

Each of the memory devices 1101 to 1114 may correspond to the memory device 100 described in FIG. 3 or FIG. 14. That is, each of the memory devices 1101 to 1114 may change a mapping between cell blocks sharing sub-word line drivers and data pads so that the number of bits of data output from the cell blocks sharing the sub-word line drivers is reduced. Accordingly, each of the memory devices 1101 to 1114 may prevent an occurrence of an uncorrectable error (UE) by limiting the maximum number of error bits that may be caused by a fault of the sub-word line driver to within the error correction capability of the ECC engine 1210 of the memory controller 1200.

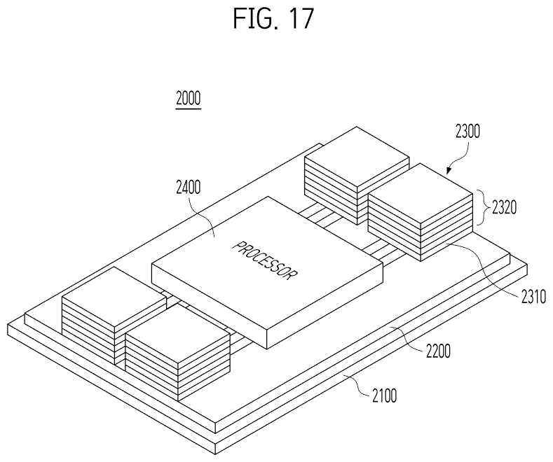

FIG. 17 is a block diagram illustrating a memory system 2000 including a stacked memory device 2300 according to an embodiment of the present disclosure.

Referring to FIG. 17, the memory system 2000 may include a package substrate 2100, an interposer 2200, stacked memory devices 2300, and a processor 2400.

The package substrate 2100 may include a printed circuit board (PCB). The package substrate 2100 may be electrically connected to an external system board, main board, or module board through bumps.

The interposer 2200 may be formed on the package substrate 2100. The interposer 2200 may be a silicon substrate in which only wiring is formed.

The one or more stacked memory devices 2300 and the processor 2400 may be formed on the interposer 2200. The stacked memory devices 2300 and the processor 2400 may be disposed on the interposer 2200 spaced apart from each other. Although four stacked memory devices 2300 are illustrated in FIG. 17, the embodiments of the present disclosure are not limited thereto, and one or more stacked memory devices may be formed on the interposer 2200.

The processor 2400 may include a memory controller and a physical interface circuit. The memory controller may be configured to control the stacked memory devices 2300. The physical interface circuit may interface between the memory controller and the stacked memory devices 2300. The physical interface circuit may be an interface circuit that converts signals transferred from the memory controller into signals suitable for use in the stacked memory devices 2300 and outputs the signals transferred from the stacked memory devices 2300 into signals suitable for use in the memory controller. The processor 2400 may be one of various processors such as a micro-processing unit (MPU), a central processing unit (CPU), a general processing unit (GPU), and a host processing unit (HPU).

Each of the stacked memory devices 2300 may include a lower chip 2310 and one or more upper chips 2320 vertically stacked on the interposer 2200. An example of the stacked memory devices 2300 formed by stacking a plurality of chips as described above may be a high bandwidth memory (HBM). Through electrodes TSV are formed between the lower chip 2310 and the upper chips 2320, through which signals (i.e., commands, addresses, and data) may be transferred between the chips.

The lower chip 2310 may include a physical interface circuit for an interface with the memory controller. Each of the upper chips 2320 may correspond to the memory device 100 described in FIG. 3 or FIG. 14. That is, each of the upper chips 2320 may change a mapping between cell blocks sharing sub-word line drivers and data pads so that the number of bits of data output from the cell blocks sharing the sub-word line drivers is reduced. Accordingly, each of the upper chips 2320 may prevent an occurrence of an uncorrectable error (UE) by limiting the maximum number of error bits that may be caused by a fault of the sub-word line driver to within an error correction capability of the memory controller.

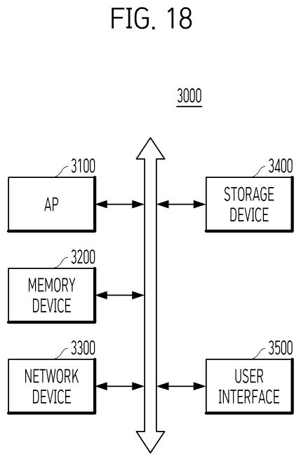

FIG. 18 is a block diagram illustrating a mobile system 3000 including a memory device 3200 according to an embodiment of the present disclosure.

Referring to FIG. 18, the mobile system 3000 may include an application processor (AP) 3100, the memory device 3200, a network device 3300, a storage device 3400, and a user interface 3500.

The application processor 3100 may drive components, an operating system (OS), or a user program included in the mobile system 3000. For example, the application processor 3100 may be provided as a system-on-chip (SoC).

The memory device 3200 may operate as a main memory, an operation memory, a buffer memory, or a cache memory of the mobile system 3000. The memory device 3200 may include a volatile random access memory such as DRAM, SDRAM, DDR SDRAM, DDR2 SDRAM, DDR3 SDRAM, LPDDR3 SDARM, LPDDR3 SDRAM, or a nonvolatile random access memory such as PRAM, ReRAM, MRAM, FRAM, etc. According to an embodiment, the memory device 3200 may be configured as the memory module 1000 described with reference to FIG. 16.

In an embodiment of the present disclosure, the memory device 3200 may correspond to the memory device 100 described in FIG. 3 or FIG. 14. That is, the memory device 3200 may change a mapping between cell blocks sharing sub-word line drivers and data pads so that the number of bits of data output from the cell blocks sharing the sub-word line drivers is reduced. Accordingly, memory device 3200 may prevent an occurrence of an uncorrectable error (UE) by limiting the maximum number of error bits that may be caused by a fault of the sub-word line driver to within an error correction capability of the application processor 3100. According to an embodiment, the memory device 3200 may be configured with the memory module 1000 described with reference to FIG. 16.

The network device 3300 may communicate with external devices. For example, the network device 3300 may support wireless communication such as Code Division Multiple Access (CDMA), Global System for Mobile Communication (GSM), Wideband CDMA (WCDMA), CDMA-2000, Time Division Multiple Access (TDMA), Long Term Evolution (LTE), Wimax, WLAN, UWB, Bluetooth, Wi-Fi, etc. For example, the network device 3300 may be included in the application processor 3100.

The storage device 3400 may store data. For example, the storage device 3400 may store data received from the application processor 3100. Alternatively, the storage device 3400 may transmit the stored data to the application processor 3100. For example, the storage device 3400 may be implemented as a nonvolatile semiconductor memory device such as a phase-change RAM (PRAM), a magnetic RAM (MRAM), a resistive RAM (RRAM), a NAND flash, a NAND flash, and a three-dimensional NAND flash.

While the embodiments of the present disclosure have been described with respect to the specific embodiments, it will be apparent to those skilled in the art that various changes and modifications may be made without departing from the spirit and scope of the invention as defined in the following claims. Furthermore, the embodiments may be combined to form additional embodiments.

What is claimed is:

1. A memory device comprising:
a memory cell array including a plurality of cell blocks, each cell block including a plurality of memory cells and sharing sub-word line drivers with adjacent cell blocks;
a data input/output circuit configured to input and output data corresponding to the plurality of cell blocks through a plurality of data pads; and
a mapping circuit disposed between the memory cell array and the data input/output circuit, and configured to control a mapping between the plurality of cell blocks and the plurality of data pads, while adjusting, according to an output control signal, a number of bits of data output from cell blocks sharing activated sub-word line drivers.

2. The memory device of claim 1, wherein the mapping circuit is configured to allocate, according to the output control signal, data output from n cell blocks among 2n cell blocks sharing the activated sub-word line drivers, into the plurality of data pads, where n is an integer greater than or equal to 1.

3. The memory device of claim 1, wherein the output control signal is generated based on at least one bit of a row address.

4. The memory device of claim 1, further comprising an output control circuit configured to generate mode information for selecting one of a plurality of modes according to a mode setting command, and generate the output control signal based on the mode information and a row address.

5. The memory device of claim 4, wherein the output control circuit includes:
a mode setting circuit configured to decode at least some bits of an input address to generate and store the mode information; and
a mapping control circuit configured to generate the output control signal based on the mode information and the row address.

6. The memory device of claim 1,
wherein the plurality of cell blocks are grouped into a plurality of cell groups, each group including two adjacent cell blocks, and
wherein each of the plurality of cell groups includes:
first word lines configured to share first sub-word line drivers with corresponding word lines of an adjacent cell group disposed in a first direction; and
second word lines alternately disposed with the first word lines in a second direction intersecting the first direction, and configured to share second sub-word line drivers with corresponding word lines of an adjacent cell group disposed in a direction opposite to the first direction.

7. The memory device of claim 6, wherein the mapping circuit is configured to map, according to the output control signal, data output from cell blocks included in one of two cell groups sharing the activated sub-word line drivers, into the plurality of data pads.

8. The memory device of claim 6, wherein the mapping circuit is configured to map, according to the output control signal, data output from a cell block included in each of two cell groups sharing the activated sub-word line drivers, into the plurality of data pads.

9. The memory device of claim 1, wherein each of the plurality of cell blocks includes:
first word lines configured to share first sub-word line drivers with corresponding word lines of an adjacent cell block disposed in a first direction; and
second word lines alternately disposed with the first word lines in a second direction intersecting the first direction, and configured to share second sub-word line drivers with corresponding word lines of an adjacent cell block disposed in a direction opposite to the first direction.

10. The memory device of claim 9, wherein the mapping circuit is configured to map, according to the output control signal, data output from one cell block among two cell blocks sharing the activated sub-word line drivers, into the plurality of data pads.

11. A memory device comprising:
a memory cell array including a plurality of cell groups, each group including two adjacent cell blocks among a plurality of cell blocks and sharing sub-word line drivers with adjacent cell groups;
a data input/output circuit configured to input and output data corresponding to the plurality of cell blocks through a plurality of data pads; and
a mapping circuit disposed between the memory cell array and the data input/output circuit, and configured to control a mapping between the plurality of cell blocks and the plurality of data pads, while adjusting a number of bits of data output from cell groups sharing activated sub-word line drivers.

12. The memory device of claim 11, wherein each of the plurality of cell groups includes:
first word lines configured to share first sub-word line drivers with corresponding word lines of an adjacent cell group disposed in a first direction; and
second word lines alternately disposed with the first word lines in a second direction intersecting the first direction, and configured to share second sub-word line drivers with corresponding word lines of an adjacent cell group disposed in a direction opposite to the first direction.

13. The memory device of claim 12, wherein the mapping circuit is configured to map data output from cell blocks included in one of two cell groups sharing the activated sub-word line drivers, into the plurality of data pads.

14. The memory device of claim 12, wherein the mapping circuit is configured to map data output from a cell block included in each of two cell groups sharing the activated sub-word line drivers, into the plurality of data pads.

15. A memory system comprising:
a memory module including a plurality of memory devices; and
a memory controller configured to provide a command and an address to control the memory module, and output and receive data to and from the memory module,
wherein at least one of the plurality of memory devices includes:
a memory cell array including a plurality of cell blocks, each block including a plurality of memory cells and sharing sub-word line drivers with adjacent cell blocks;
a data input/output circuit configured to input and output the data of the plurality of cell blocks through a plurality of data pads; and
a mapping circuit disposed between the memory cell array and the data input/output circuit, and configured to control a mapping between the plurality of cell blocks and the plurality of data pads, while adjusting, according to an output control signal, a number of bits of data output from cell blocks sharing activated sub-word line drivers.

16. The memory system of claim 15, wherein the mapping circuit is configured to map, according to the output control signal, data output from n cell blocks among 2n cell blocks sharing the activated sub-word line drivers, into the plurality of data pads, where n is an integer greater than or equal to 1.

17. The memory system of claim 15, wherein the output control signal is generated based on at least one bit of a row address.

18. The memory system of claim 15,
wherein the plurality of cell blocks are grouped into a plurality of cell groups, each group including two adjacent cell blocks, and
wherein each of the plurality of cell groups includes:
first word lines configured to share first sub-word line drivers with corresponding word lines of an adjacent cell group disposed in a first direction; and
second word lines alternately disposed with the first word lines in a second direction intersecting the first direction, and configured to share second sub-word line drivers with corresponding word lines of an adjacent cell group disposed in a direction opposite to the first direction.

19. The memory system of claim 18, wherein the mapping circuit is configured to map, according to the output control signal, data output from cell blocks included in one of two cell groups sharing the activated sub-word line drivers, into the plurality of data pads.

20. The memory system of claim 18, wherein the mapping circuit is configured to map, according to the output control signal, data output from a cell block included in each of two cell groups sharing the activated sub-word line drivers, into the plurality of data pads.
